(19) United States
(12) Patent Application Publication
(10) Pub. No.: US 2002/0042212 A1
(43) Pub. Date: Apr. 11, 2002

(54) Connector for a low-profile miniature card

(76) Inventors: Alexis Michaud, Pontarlier (FR); Laurent Vuillemin, St-Gorgon Main (FR)

Correspondence Address: PERMAN & GREEN, 425 POST ROAD, FAIRFIELD, CT, 06430, US

(21) Appl. No.: 09/930,621

(22) Filed: Aug. 15, 2001

Related U.S. Application Data
(63) Continuation-in-part of application No. 09/335,106, filed on Jun. 17, 1999, now abandoned.

(30) Foreign Application Priority Data
Jun. 26, 1998 (FR) FR 98/08166

(51) Int. Cl. H05K 1/00

(52) U.S. Cl. 439/66

(57) ABSTRACT

A connector for a smart-card reader comprising an insulating support and electrical contacts fastened in the insulating support for electrically connecting a smart-card to the smart-card reader. Each electrical contact comprises a contact blade that is adapted to make electrical contact with a card when a card is inserted into the smart-card reader and a fixation leg for connecting the contact to a printed circuit board, the fixation leg being disposed on a side of the contact blade and staggered from the contact blade along a longitudinal axis of the blade. The fixation leg does not project outside of the outer dimensions of the connector and is adapted to make electrical contact with a contact pad on a printed circuit board.

### CROSS-REFERENCE TO RELATED APPLICATIONS

This application is a continuation-in-part of copending U.S. patent application Ser. No. 09/335,106, filed on Jun. 17, 1999.

### BACKGROUND OF THE INVENTION

1. Field of the Invention

The present invention relates to connectors for smart-card readers and, more particularly, to a connector for a smart-card reader with reduced dimensions and overall size.

2. Brief Description of Related Developments

Connectors for smart-card readers which are known in the prior art generally comprise two rows of contacts which are oriented in opposite directions, one with respect to the other. In order to keep the contacts lying in the second row in their housings, each of the contacts must be pre-stressed and thus exert a force on the upper wall of the insulation which, in order to withstand this force, must have a minimum thickness. Moreover, in this type of connector, the contacts are fastened in the insulation by harpoons which are lodged in a transverse cavity. This also has the effect of increasing the volume of the connectors and is a disincentive to them being used in applications requiring greater and greater miniaturization, as is the tendency, for example, in card readers fitted into GSM mobile telephones.

Furthermore, in applications relating to SMC (surface mounted component) soldering, the contact area between each metal contact and the contact pad on the printing circuit must be as large as possible if it is desired to exert a relatively high force on the component, for example when the card is being inserted into the reader.

In prior art smart card connectors, the electrical contacts usually include a portion, such as a contact tail, that extends or projects outside the outer dimensions of the connector housing in order for the contacts to make electrical contact with a printed circuit board. An example of such a connector is disclosed in U.S. Pat. No. 5,746,607. The smart card electrical connector includes electrical contacts that have resiliently deflectable contact tails projecting beneath the body of the connector housing. The trace engaging portion of the contact tails must project beneath a lower bearing face of the body of the connector in order to engage the circuit board. This increases the overall size of the connector and is an impediment to miniaturization of the connector.

### SUMMARY OF THE INVENTION

The present invention is directed to a connector for a smart-card reader. In one embodiment, the connector comprises an insulating support and electrical contacts fastened in the insulating support for electrically connecting the smart-card to the smart-card reader. Each electrical contact comprises a contact blade that is adapted to make electrical contact with a card when a card is inserted into the smart-card reader and a fixation leg for connecting the contact to a printed circuit board disposed on a side of the contact blade and staggered from the contact blade along a longitudinal axis of the blade. The fixation leg does not project outside of the outer dimensions of the connector and is adapted to make electrical contact with a contact pad on a printed circuit board.

In one aspect, the present invention is directed to an electrical connector for a card reader. In one embodiment the invention comprises an insulating support having a plurality of openings and at least one electrical contact adapted to be housed in a respective one of the openings in the insulating support. Each electrical contact is adapted to make electrical contact with a card inserted into a card reader and a printed circuit board on an opposite side of the connector from the card. Each electrical contact in the connector comprises a contact blade portion adapted to make an electrical connection with the card, an intermediate portion that is turned on itself, and a fixation member extending from a lower portion of the contact. The fixation member is adapted to be soldered to the printed circuit board in order to create an electrical connection between the contact and the printed circuit board.

In another aspect, the present invention is directed to an electrical contact for a card-reader connector. In one embodiment the contact comprises a contact blade portion adapted to electrically engage a respective portion of a card inserted into the card reader, and a fixation leg adapted to be electrically connected to an electrical contact on a printed circuit board of a card-reader. The fixation leg includes an opening adapted to wick up solder by capillary effect when the fixation leg is soldered to the electrical contact on the printed circuit board. The fixation leg is also adapted to not extend beyond an outer plane of an insulating support in which the contact is secured.

### BRIEF DESCRIPTION OF THE DRAWINGS

The foregoing aspects and other features of the present invention are explained in the following description, taken in connection with the accompanying drawings, wherein:

FIG. 1 is a perspective view of one embodiment of a portion of a smart-card connector according to the present invention.

FIG. 2 is a top view of the connector shown in FIG. FIG. 3 shows a side view of the connector shown in FIG. 1.

FIG. 4 is a perspective view of one embodiment electrical contact incorporating features of the present invention.

FIG. 5 is a bottom view of the connector shown in FIG. 1.

### DETAILED DESCRIPTION OF THE PREFERRED EMBODIMENTS

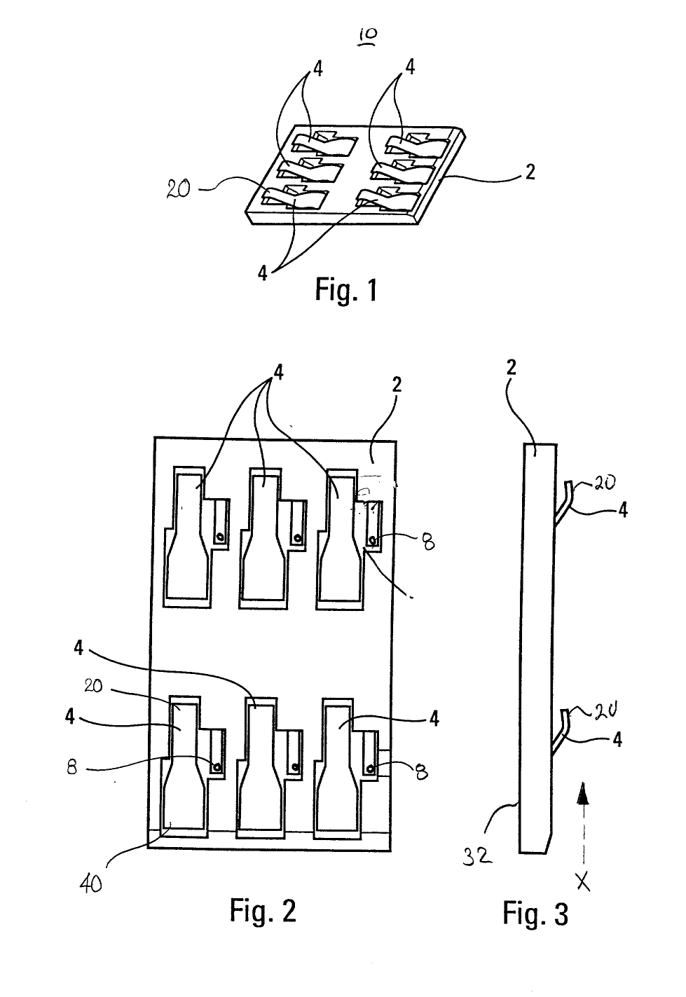

Referring to FIG. 1, there is shown a perspective view of a connector 10 incorporating features of the present invention. Although the present invention will be described with reference to the single embodiment shown in the drawings, it should be understood that the present invention can be embodied in many alternate forms of embodiments. In addition, any suitable size, shape or type of elements or materials could be used.

FIG. 1 illustrates a portion of a connector 10 for a smart-card reader. For purposes of this invention and description, only the portion of the smart card reader connector housing the electrical contacts of the connector will be described. In one embodiment, the connector 10 comprises an insulating support or housing 2 into which electrical contacts 4 intended for electrically connecting the smart card to a printed circuit are fastened. As may be seen in FIGS. 1 and 2, and in particular in FIG. 3, the contacts 4 are all oriented in the same direction so as to prevent the contacts 4 from turning up when a smart card is being inserted into the card reader. Generally, a card is inserted into the card reader in a direction of an insertion axis indicated as X in FIG. 3. The electrical contact 4 includes a blade portion 20, also referred to herein as a card contact portion, that is adapted to make electrical contact with a card inserted into a card reader connector. The blade portion 20 generally projects above a surface of the insulating support 2 in order to contact the card. As shown in FIGS. 1 and 3, only the blade portion 20 projects outside the outer dimensions of the insulating support 2. It is a feature of the present invention to limit the overall size of the connector by containing the remainder of the electrical contact 4 within the dimensions of the insulating support 2.

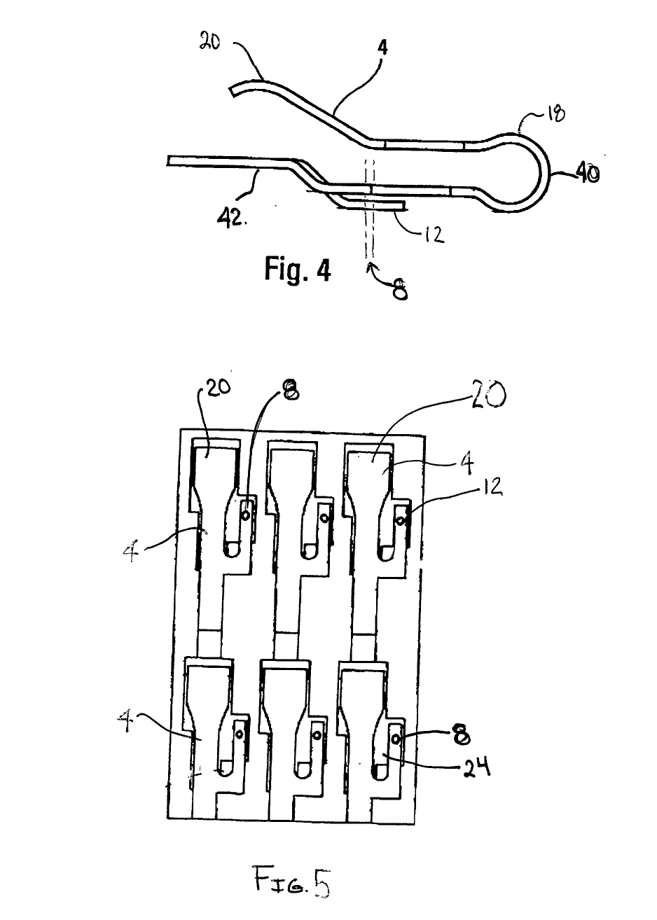

Referring to FIG. 4, each electrical contact 4 may be a one-piece member which is bent on itself to generally comprise an electrically conductive strip having a card contact portion or blade portion 20, an intermediate portion 40 bent on itself and a lower portion 42. The lower portion 42 includes a fixation leg 12 that can be disposed to one side of the lower portion of the contact 4 (see also FIG. 5). The fixation leg 12 is adapted to engage a corresponding contact pad or trace on the printed circuit board of the card reader device. Generally, the card reader connector is electrically and mechanically coupled to a printed circuit board. The contacts 4 are used to electrically connect a card to the printed circuit board when the card is inserted into the connector.

The fixation leg or pad 12 is disposed on one side of the contact 4 and can lie in a substantially horizontal plane below the lower portion 42 of the contact 4. In an alternate embodiment, the fixation leg 12 can be disposed in any suitable position or plane. It is feature of the present invention to keep the fixation leg contained within the outer dimensions of the insulating support 2 (see FIG. 3). As shown in FIGS. 4 and 5, the fixation leg 12 is disposed on a side of the contact 4 and staggered aside from the contact blade 20. Generally, the leg 12 is disposed offset from the longitudinal axis of the contact 4. As shown in FIG. 4, the position of leg 12 of the contact 4 can also extend juxtaposed and below the lower part portion 42 of the contact 4. It is a feature of the invention that the contact fixation leg 12 is shifted in the longitudinal axis of the contact blade 20 and can be soldered to the printed circuit board.

Referring to FIG. 2 and 5, an opening 24 in the insulating support 2 allows access to the leg 12 in order to solder the contact to the printed circuit board of the card reader. It is a feature of the present invention to be able to solder the legs 12 to the printed circuit board from above the insulating support 2. As shown in FIGS. 2 and 5, each fixation leg 12 can also include an opening or hole 8 intended to allow the solder to wick up by capillary effect. The hole 8 on the part of the leg 12 intended to bear on an electrical contact on the printed circuit board allows the solder to wick up by capillary effect when it is soldered or when it passes through an oven or soldering station. It is a feature of the present invention to improve the effectiveness of the fastening of the leg 12 to the printed circuit board by soldering. This technique is particularly advantageous when it is used for products having to withstand large forces, for example when a card is being inserted or when a device fitted with such a connector is being placed on a battery charger.

Referring to FIG. 4, the card engaging portion or contact blade 20 of the contact 4 is generally shaped to be curved with a convex surface facing upwardly, although in alternate embodiments, any suitable shape can be used. The card-engaging portion 20 is generally resiliently deflectable and can be urged in an upward direction. Generally, the card-engaging portion 20 is adapted to move in an up and down direction as a card is inserted into the card reader. The card-engaging portion 20 is adapted to provide a sufficient contact force against the card to maintain a proper electrical contact between the card engaging portion 20 and a corresponding area on the card. The intermediate portion 40 is formed by the contact 4 being bent upon itself and is generally circular in shape.

Referring to FIG. 5, in the preferred embodiment, the contacts 4 are fastened to the insulating support 2 from underneath the connector 10, thus making it possible to dispense with the plastic part lying at the bottom of the connector. In the present invention, the contacts 4 are no longer fastened to the insulating support, as in the prior art, by harpoons lodged in a transverse cavity. The contact 4 can be fastened in the insulating support 2 by cold mechanical deformation or ultrasound. It is a feature of the present invention to produce a very thin connector of very significantly reduced dimensions, in which the contacts are kept in their housings without any prestress. The fastening of the contacts 4 to the insulating support 2 can be either by ultrasound or by cold deformation of the plastic of the insulating support. The deformation is carried out from underneath, from the bottom upwards, thereby reducing the thickness of the connector even more.

The present invention eliminates the need to prestress the contacts of the second row and makes it possible to reduce the thickness of the upper wall of the insulating support of housing 2.

The position of the legs 12, between each main contact 4 which is in connection with the smart card, also makes it possible to contribute to significantly reducing the external dimensions of the connector. In fact, the legs 12, which do not extend beyond the sides of the connector 10, make it possible to reduce the length of the product by the length of the pads, i.e. by approximately 1 mm in the case of the SMC pads, taking into account the bending in order to allow passage of the punches.

In the present invention, only the card contact portion 20 of the electrical contact 4 projects or extends outside the outer dimensions of the insulating support 2. The remainder of the contact 4, including a trace engaging portion or fixation leg 12 shown in FIG. 4, is contained within the outer boundaries of the insulating support 2. This reduces the overall dimensions of a smart card reader connector and allow for miniaturization of the card reader.

It should be understood that the foregoing description is only illustrative of the invention. Various alternatives and modifications can be devised by those skilled in the art without departing from the invention. Accordingly, the present invention is intended to embrace all such alternatives, modifications and variances that fall within the scope of the appended claims.

What is claimed is:

1. A connector for a smart-card reader comprising:
an insulating support; and
electrical contacts fastened in the insulating support for electrically connecting a smart-card to the smart-card reader, wherein each electrical contact comprises:
a contact blade adapted to make electrical contact with a card when a card is inserted into the smart-card reader; and
a fixation leg for connecting the contact to a printed circuit board, the fixation leg being disposed on a side of the contact blade and staggered from the contact blade along a longitudinal axis of the blade.

2. The connector of claim 1 wherein the insulating support further includes an opening to allow access to the fixation leg from above the insulating support in order to solder the fixation leg to a printed circuit board.

3. The connector of claim 1 wherein the fixation leg is adapted to be soldered to a printed circuit board from above the insulating support via an opening in the insulating support.

4. The connector of claim 1 wherein the fixation legs do not project outside an outer dimension of the insulating support.

5. The connector of claim 1 wherein the contact is bent on itself.

6. The connector of claim 1 wherein a direction of orientation of each electrical contact is the same as a direction of insertion of a smart card into the reader.

7. The connector of claim 1 wherein the electrical contacts are fastened to the insulating support by cold mechanical deformation or by ultrasound.

8. The connector according to claim 1 wherein each fixation leg includes at least one hole therein that allows solder to be wicked up by capillary effect when the leg is soldered to a printed circuit board.

9. An electrical connector for a card reader comprising:
an insulating support having a plurality of openings;
at least one electrical contact adapted to be housed in a respective one of the openings in the insulating support, each electrical contact being adapted to make electrical contact with a card inserted into a card reader and a printed circuit board on an opposite side of the connector from the card, wherein each electrical contact comprises:
a contact blade portion adapted to make an electrical connection with the card;
a intermediate portion that is turned on itself; and
a fixation member extending from a lower portion of the contact, the fixation member adapted to be soldered to the printed circuit board in order to create an electrical connection between the contact and the printed circuit board.

10. The connector of claim 9 wherein the fixation member further comprises a trace engaging portion adapted to engage the printed circuit board, the trace engaging portion including a hole adapted to wick up solder by capillary effect.

11. The connector of claim 9 wherein each opening in the insulating support allows a user to access the fixation member when the connector is positioned on the printed circuit board in order to solder the fixation member to the printed circuit board.

12. The connector of claim 9 wherein the fixation member does not extend beyond an outer dimension of the insulative support in order to electrically engage the printed circuit board.

13. The connector of claim 9 wherein the fixation member is juxtaposed along the lower portion of the contact and extends along a longitudinal axis of the contact blade portion.

14. The connector of claim 9 wherein the fixation member further includes an opening adapted to allow solder to wick up by capillary effect when the fixation member is soldered to the printed circuit board.

15. The connector of claim 9 wherein the insulating support further includes at least one opening to allow access to the fixation member in order to solder the fixation member to the printed circuit board.

16. The connector of claim 9 wherein the contact blades are each oriented in a direction corresponding to an insertion direction of a card into the card reader.

17. The connector of claim 9 wherein the electrical contacts are retained in the insulating support without any prestress.

18. An electrical contact for a card-reader connector comprising:
a contact blade portion adapted to electrically engage a respective portion of a card inserted into the card reader; and
a fixation leg adapted to be electrically connected to an electrical contact on a printed circuit board of a card-reader, the fixation leg including an opening adapted to wick up solder by capillary effect when the fixation leg is soldered to the electrical contact on the printed circuit board, and wherein the fixation leg is adapted to not extend beyond an outer plane of an insulating support in which the contact is secured.

19. The contact of claim 18 wherein the contact is bent upon itself.

20. The contact of claim 19 wherein the fixation leg is disposed aside of a longitudinal axis of the contact.
